(19) United States
(12) Patent Application Publication
(10) Pub. No.: US 2005/0191863 A1
(43) Pub. Date: Sep. 1, 2005

(54) Semiconductor device contamination reduction in a fluorinated oxide deposition process

(76) Inventors: Leonard Jay Olmer, Orlando, FL (US); Thomas James Lahey, Windermere, FL (US); Timothy Scott Campbell, Allentown, PA (US); Robert William Schanzer, Orlando, FL (US); David Mark Shuttleworth, Orlando, FL (US)

Correspondence Address: BEUSSE BROWNLEE WOLTER MORA & MAIRE, P.A., 390 N. ORANGE AVENUE, SUITE 2500, ORLANDO, FL, 32801, US

(21) Appl. No.: 11/039,354

(22) Filed: Jan. 20, 2005

Related U.S. Application Data
(60) Provisional application No. 60/542,006, filed on Feb. 5, 2004.
(60) Provisional application No. 60/614,665, filed on Sep. 30, 2004.

(51) Int. Cl. B05D 1/36; B05D 7/00; H01L 21/4763; H01L 21/31; H01L 21/469

(52) U.S. Cl. 438/763; 427/419.3; 438/761; 438/781; 438/784

(57) ABSTRACT

A method for improving throughput in a semiconductor wafer deposition process in a high density plasma chamber includes processing a first wafer in the high density plasma chamber using a process that includes high power sufficient to burn fluorosilicate glass residue in the chamber. The method further includes removing the first wafer and processing additional wafers using the same process without cleaning the chamber between wafers.

### SPECIFIC DATA RELATED TO THE INVENTION

This application claims benefit of the Feb. 5, 2004 filing date of U.S. provisional application No. 60/542,006 and U.S. provisional application No. 60/614,665 filed Sep. 30, 2004.

### FIELD OF THE INVENTION

The present invention relates to semiconductor devices, and, in particular, to a method for reducing semiconductor device contamination problems occurring in a semiconductor device manufacturing process.

### BACKGROUND OF THE INVENTION

Contamination is a common problem encountered in semiconductor device manufacturing processes. One semiconductor device manufacturing process includes depositing fluorosilicate glass (FSG) on a surface of a multi-layer semiconductor wafer to form an inter-layer dielectric between conductors in the wafer by exposing the wafer to a high density plasma (HDP) comprised of silicon and fluorine containing precursors. The HDP process may include a sputtering deposition and chemical component which typically is used to form about a 16,000 angstrom dielectric layer on the semiconductor wafer. The sputtering of the FSG may be controlled by applying an electrical bias to the wafer. When the wafer is highly biased, there is a low deposition rate because the sputtering removes some of the deposition. Once the dielectric has filled between conductor lines of the wafer, the applied bias may be reduced or turned off so that the deposition rate can be increased because the lower bias no longer causes a high rate of ion impingement of the material on the surface and sputtering decreases. The bias may be required with the sputtering in order to fill gaps between the conductor lines. Chemical etching may also occur using FSG in this process.

The typical dielectric used in the deposition process is SiH₄+O₂, and sometimes argon. The actual dielectric then becomes an SiₓOₓF₂ when the SiF4 is added to the gas mix. The FSG lowers the dielectric constant of the dielectric which improves the electrical characteristics for such semiconductors. For example, the use of FSG may drop the dielectric constant from approximately 4 to about 3.7. In the HDP process, there is typically an introduction of an oxygen and/or argon plasma that is designed to heat the wafer to approximately 400 degrees centigrade (C). The HDP process may be performed with oxygen alone, argon alone, or a combination of the two.

One of the problems resulting from the use of FSG as a dielectric is that the FSG can release fluorine that will diffuse out of the dielectric and attack metal or other layers of the semiconductor. This fluorine is also present on the surfaces and within the byproducts deposited in the deposition chamber so that subsequent wafer processing in the chamber may result in contamination from this fluorine. One solution to this problem has been to coat the wafer surfaces in the chamber with a silicon-rich oxide layer, such as SiO_{1.9} which acts as a diffusion barrier to the fluorine diffusion. Another solution may be to lower the fluorine content in a deposited FSG layer, but this solution may be undesirable because this would limit the ability of the FSG to lower the dielectric constant of the layer to a desired value.

Another solution that has been shown to prevent fluorine contamination to wafers being processed in the chamber is to clean the HDP chamber with an etching gas so that the fluorine contamination is removed. Subsequent to the cleaning, the chamber can be purged using Silane gas to get rid of any residual fluorine and then the chamber walls can be coated with silicon dioxide to protect the chamber walls and cover any other remaining fluorine compounds on the walls and process kit.

When a chamber has been cleaned as described above, the wafer may be processed in the chamber without being exposed to contamination. To save time, a second wafer may be processed without cleaning the chamber after processing a first wafer. However, it has been discovered that a second wafer processed without cleaning the chamber may be contaminated with fluorine, resulting in a high electrical failure rates of the second wafers. It is believed this problem may be caused from the high density plasma reacting with the fluorine-containing chamber walls and chamber parts, causing an undesirable fluorine containing material to be deposited on the wafer prior to the FSG deposition. For example, after the introduction of a plasma to heat a second wafer in an uncleaned chamber, the chamber is used to deposit a silicon rich layer onto the metal of the wafer that would be designed to protect the metal from the active fluorine in the FSG. However, since the initial heating step may have caused the fluorine in the chamber to deposit onto the metal, the silicon rich layer may have just over-coated the fluorine that was already on the metal.

FIG. 1 illustrates the results of contamination 12 caused by a fluorine rich film being formed under a silicon rich layer that occurs on a second wafer 10 in a high density plasma operation. FIG. 2 shows another form of contamination 12 caused by etching out of a silicon rich oxide. An analysis of failures of second wafers processed in an uncleaned chamber has determined that the wafer failures occurred in primarily circular patterns around the edges of the wafer rather than uniformly spread over the wafer. This pattern suggested that the contamination may be derived from sources other than the chamber walls.

In further analysis of this problem, it was noted that the chamber walls are a metal and ceramic material such as aluminum and aluminum oxide, respectively that when the wafer is placed in the chamber, it is placed on a fixture that supports the wafer and that such exposed portions of the fixture are protected from the plasma by an aluminum oxide ceramic ring. Since the ceramic covered portions of the fixture are circular and extend beyond the edges of a wafer placed in the chamber, applicants hypothesized that the pattern of defects on the wafer surface suggests that the contaminating material may have been fluorine that is being drawn out of the ceramic fixture rather than fluorine being drawn from the chamber walls. More particularly, applicants determined that the surface area of the ceramic holding fixture or process kit for the wafer increases due to roughness and captures more fluorine that can be deposited onto the wafer as the kit is used. FIGS. 3-6 are photographs of a process kit 14 used to support the wafer in the high density plasma chamber and illustrates the various amounts of contamination 12 caused by flaking of fluorine contaminated materials. FIG. 7 illustrates a chamber 16 in which the wafer is processed and shows that the contamination appears to be localized to the ceramic process kit.

As noted above, the problems appear when a second or other wafer is processed in the chamber prior to a complete cleaning of the chamber. However, such a process of foregoing cleaning is necessary in order to increase the throughput and reduce the cost of manufacturing wafers. The present invention is directed to solutions to this problem which allow multiple wafers to be processed without having to perform a cleaning step of the chamber between each wafer.

### BRIEF DESCRIPTION OF THE DRAWINGS

FIG. 1 illustrates the results of contamination caused by a fluorine rich film being formed under a silicon rich layer that occurs on a second wafer in a high density plasma operation.

FIG. 2 shows another form of contamination caused by etching out of a silicon rich oxide.

FIGS. 3-6 are photographs of the process kit used to cover the exposed portions of the wafer chuck and illustrates the various amounts of contamination caused by flaking of the fluorine contaminated materials.

FIG. 7 illustrates a chamber in which the wafer is processed and shows that the contamination appears to be localized to the ceramic process kit.

FIG. 8 shows a flow chart for reducing wafer contamination in a fluorinated oxide deposition process.

FIG. 9 shows a flow chart for reducing wafer contamination in a fluorinated oxide deposition process.

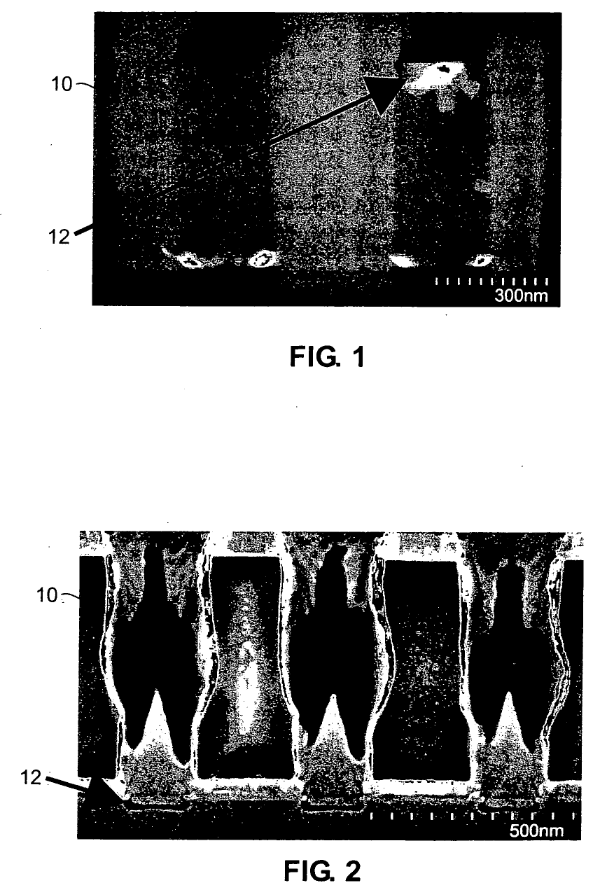

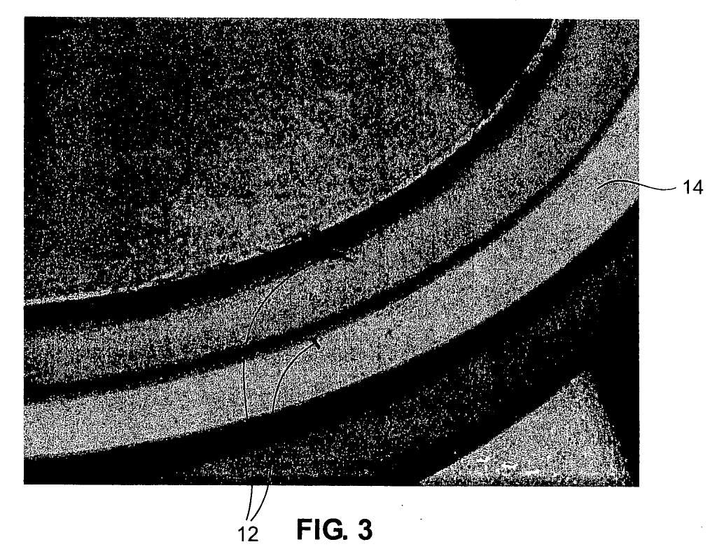

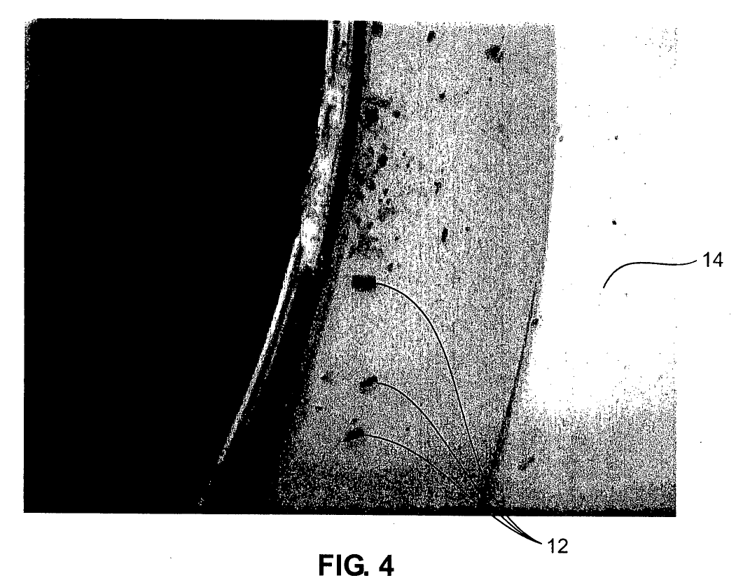

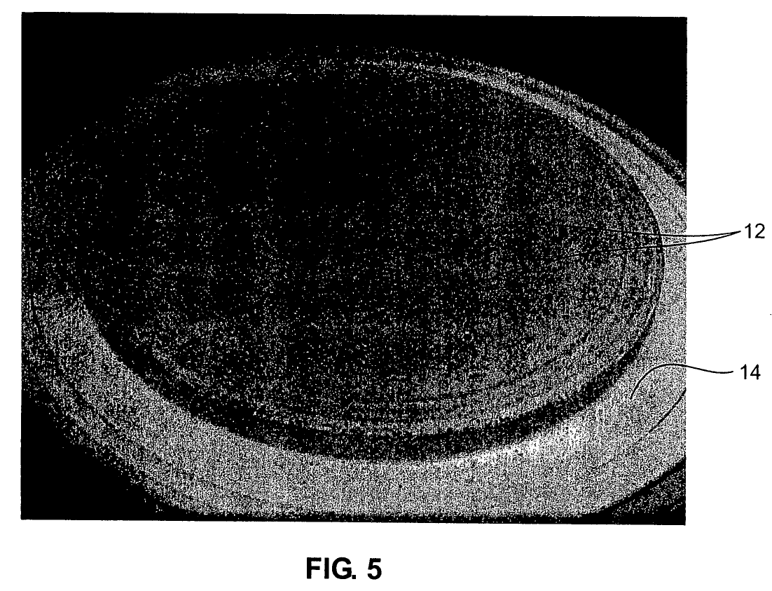

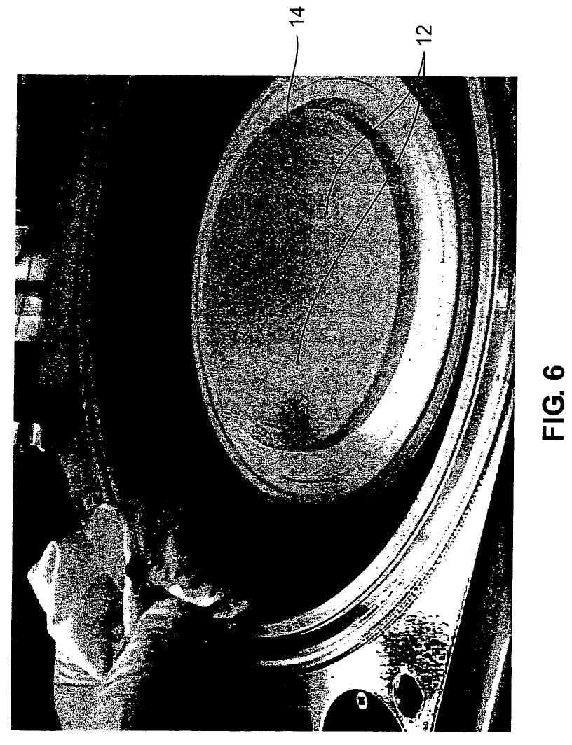

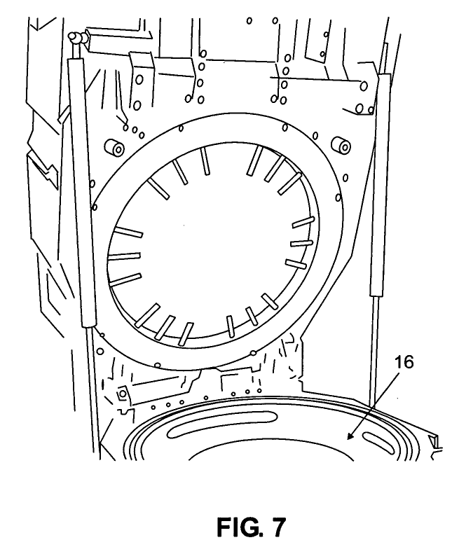

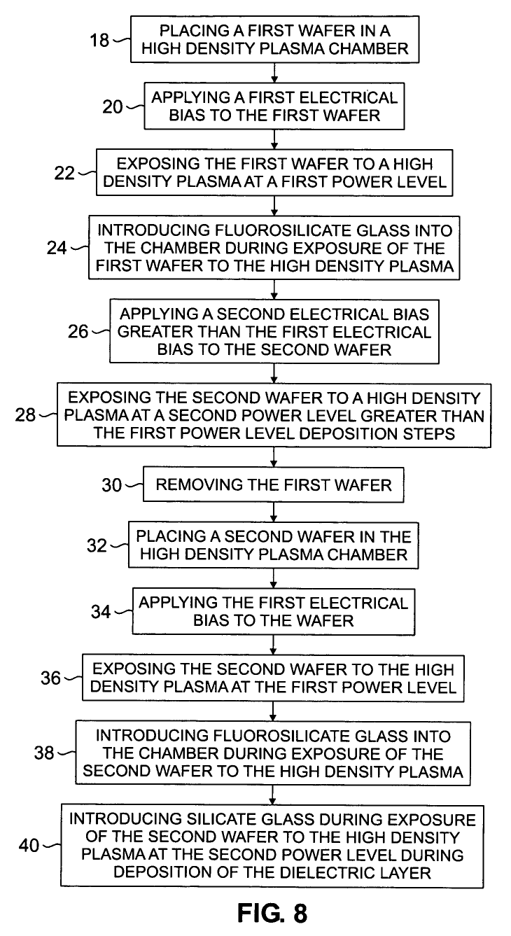

It is to be understood that the following detailed description is exemplary and explanatory only and is not to be viewed as being restrictive of the present, as claimed. These and other aspects, features and advantages of the present invention will become apparent after a review of the following description of the preferred embodiments and the appended claims.

### DETAILED DESCRIPTION OF THE INVENTION

The inventors have developed innovative solutions for improving throughput in a semiconductor wafer deposition process in a high density plasma chamber by reducing wafer contamination in a fluorinated oxide deposition process, in particular, for a second or additional wafers processed in an HDP chamber after a first wafer has been processed. In one embodiment of the invention, a process for reducing contamination includes exposing the chamber to an oxygen plasma before the second wafer is placed in the chamber. While this method may remove or react with any FSG or free fluorine that has been captured in the material in the chamber, this process may affect a manufacturing process throughput of the chamber because it requires cleaning the chamber after processing each wafer.

In another embodiment, a process for reducing contamination includes depositing an undoped silicon dioxide film before the second wafer is placed in the chamber. This process simply requires that once the first wafer is removed, the chamber is closed and an undoped silicon dioxide introduced into the plasma chamber so that it deposits and “seasons” all of the other materials in the chamber to provide a protective film and prevent fluorine or other contaminants from being released in a subsequent high density plasma operation, such as an FSG deposition process.

In another embodiment depicted in FIG. 8 a process for reducing contamination includes using a two-step FSG process. In particular, the process involves introduction of FSG in a first step using an HDP, and then a second step in which an electrical bias applied to the wafer is decreased and undoped silicon glass or FSG is introduced. The second step may be done at a much higher power and at a lower electrical bias so that the high power is sufficient to burn off any residue in the chamber from the FSG in the first part of the process so that the contamination is eliminated. Using this two-step FSG process, no interruption of the overall semiconductor manufacturing process is required, nor is any additional time added to the overall process.

As shown in FIG. 8, the method includes placing a first wafer in a high density plasma chamber 18, applying a first electrical bias to the first wafer 20, and then exposing the first wafer to a high density plasma at a first power level 22. The method further includes depositing fluorosilicate glass into the chamber during exposure of the first wafer to the high density plasma at the first power level to deposit a dielectric layer 24, applying a second electrical bias less than the first electrical bias to the first wafer 26, and exposing the first wafer to a high density plasma at a second power level greater than the first power level 28 so that the second power level is sufficiently high to burn off a fluorine residue deposited in the chamber during prior deposition steps.

After burning off the fluorine residue, the method includes removing the first wafer 30 and placing a second wafer in the high density plasma chamber 32. The method then includes applying the first electrical bias to the second wafer 34, exposing the second wafer to the high density plasma at the first power level 36, and depositing fluorosilicate glass into the chamber during exposure of the second wafer to the high density plasma at the first power level during deposition of a dielectric layer 38. After a desired period of deposition, the method introducing silicate glass during exposure of the second wafer to the high density plasma at the second power level during deposition of the dielectric layer 40.

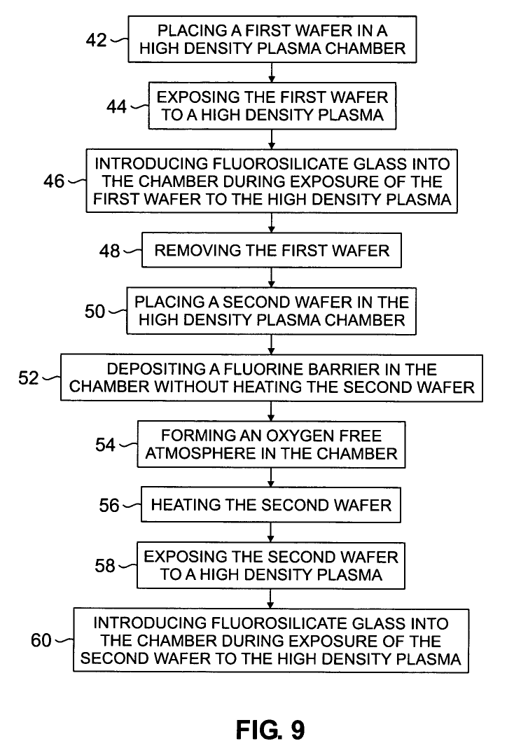

In another embodiment depicted in FIG. 9, a process for improving throughput and reducing contamination includes depositing a fluorine barrier soon after the second wafer is placed in the chamber and prior to heating the wafer in an HDP process, such as before deposition using the fluorosilicate glass. The fluorine barrier may be a silicon rich layer such as SiO_{1.9} and may be deposited using a high density plasma process. Following this step, the wafer heatup should occur in an oxygen-free plasma so as not to oxide the silicon rich layer and alter its fluorine diffusion barrier properties. For example, the heatup step may occur in an argon plasma. This fluorine barrier process may also be used before performing the two-step FSG process described above.

As shown in FIG. 9, the method includes placing a first wafer in a high density plasma chamber 42 exposing the first wafer to a high density plasma 44 introducing a fluorosilicate glass into the chamber during exposure of the first wafer to the high density plasma to deposit a dielectric layer 46 and removing the first wafer 48 after a desired deposition is complete.

The method further includes placing a second wafer in the high density plasma chamber 50, depositing a fluorine barrier in the chamber without heating the second wafer 52, and forming an oxygen free atmosphere in the chamber 54. The method further includes heating the second wafer 56, exposing the second wafer to a high density plasma 58; and introducing a fluorosilicate glass into the chamber during exposure of the second wafer to the high density plasma during deposition of a dielectric layer 60.

Although several embodiments of the present invention and its advantages have been described in detail, it should be understood that mutations, changes, substitutions, transformations, modifications, variations, and alterations can be made therein without departing from the teachings of the present invention, the spirit and scope of the invention being set forth by the appended claims.

1. A method for improving throughput in a semiconductor wafer deposition process in a high density plasma chamber comprising:
placing a first wafer in a high density plasma chamber;
applying a first electrical bias to the first wafer;
exposing the first wafer to a high density plasma at a first power level;
depositing fluorosilicate glass in the chamber during exposure of the first wafer to the high density plasma at the first power level to deposit a dielectric layer;
applying a second electrical bias less than the first electrical bias to the first wafer;
exposing the first wafer to a high density plasma at a second power level greater than the first power level so that the second power level is sufficiently high to burn off a fluorine residue deposited in the chamber during prior deposition steps;
removing the first wafer;
placing a second wafer in the high density plasma chamber;
applying the first electrical bias to the second wafer;
exposing the second wafer to the high density plasma at the first power level;
depositing fluorosilicate glass into the chamber during exposure of the second wafer to the high density plasma; and
introducing silicate glass prior to exposure of the second wafer to the high density plasma at the first power level during deposition of the dielectric layer.

2. The method of claim 1, wherein the silicate glass is undoped silicate glass.

3. The method of claim 1, further comprising depositing a fluorine barrier in the chamber before exposing the second wafer to the high density plasma at the first power level.

4. The method of claim 3, wherein the fluorine barrier comprises a silicon rich oxide layer.

5. The method of claim 1, further comprising:
removing the second wafer; and
cleaning the chamber.

6. A method for improving throughput in a semiconductor wafer deposition process in a high density plasma chamber comprising:
placing a first wafer in a high density plasma chamber;
exposing the first wafer to a high density plasma;
introducing a fluorosilicate glass into the chamber during exposure of the first wafer to the high density plasma to deposit a dielectric layer;
removing the first wafer;
placing a second wafer in the high density plasma chamber;
depositing a fluorine barrier in the chamber without heating the second wafer;
forming an oxygen free atmosphere in the chamber;
heating the second wafer;
exposing the second wafer to a high density plasma; and
introducing a fluorosilicate glass into the chamber during exposure of the second wafer to the high density plasma during deposition of a dielectric layer.

7. The method of claim 6, wherein the fluorine barrier comprises a silicon rich oxide layer.

8. The method of claim 7, wherein the silicon rich oxide layer comprises SiO_{1.9.}

9. The method of claim 6, wherein forming the oxygen free atmosphere comprises introducing argon into the chamber.

10. The method of claim 1, further comprising:
removing the second wafer; and
cleaning the chamber.

11. A method for improving throughput in a semiconductor wafer deposition process in a high density plasma chamber comprising:
processing a first wafer in the high density plasma chamber using a process that includes high power sufficient to burn fluorosilicate glass residue in the chamber; and
removing the first wafer and processing additional wafers using the same process without cleaning the chamber between wafers.
